(19) United States
(12) Patent Application Publication
(10) Pub. No.: US 2023/0318540 A1
(43) Pub. Date: Oct. 5, 2023

(54) LOW NOISE AMPLIFIER AND METHOD OF CONTROLLING AMPLIFIER CIRCUIT

(71) Applicant: LAPIS Technology Co., Ltd., Yokohama (JP)

(72) Inventor: Toru YOSHIOKA, Yokohama (JP)

(73) Assignee: LAPIS Technology Co., Ltd., Yokohama (JP)

(21) Appl. No.: 18/192,656

(22) Filed: Mar. 30, 2023

(30) Foreign Application Priority Data
Mar. 30, 2022 (JP) 2022-057745

(51) Int. Cl. H03F 3/193; H03F 1/26

(52) U.S. Cl. CPC H03F 3/193; H03F 1/26; H03F 2200/294

(57) ABSTRACT

A low noise amplifier and a method of controlling an amplifier circuit that can enable detection of a fault are provided. The low noise amplifier includes an amplifier circuit. The amplifier circuit includes an amplification transistor configured to amplify a signal input from an input terminal and to output the amplified signal to a first node, a current mirror circuit configured to supply a bias current to the amplification transistor, a resistor provided on a feedback path for feeding an output of the first node back to the input terminal, and a first switch provided on the feedback path and configured to set up or cut off the feedback path. The feedback path is cut off by the first switch when detection of a fault of the amplification transistor is performed.

### CROSS REFERENCE TO RELATED APPLICATION

This application claims priority under 35 USC 119 from Japanese Patent application No. 2022-057745 filed on Mar. 30, 2022, the disclosure of which is incorporated by reference herein.

### BACKGROUND

### Technical Field

The disclosure relates to a low noise amplifier and a method of controlling an amplifier circuit.

### Description of Related Art

In the related art, a low noise amplifier including a feedback resistor is known as a low noise amplifier for amplifying a high-frequency signal with low noise. For example, Japanese Patent Laid-Open No. 2014-116889 discloses a low noise amplifier including a first transistor configured to amplify a high-frequency signal input from an input terminal and to output the amplified high-frequency signal to a first output terminal, a first feedback circuit loaded between the input terminal and the first output terminal, a second transistor configured to amplify the high-frequency signal input from the input terminal and to output the amplified high-frequency signal to a second output terminal, a third transistor configured to amplify the high-frequency signal input from the first output terminal and to output the amplified high-frequency signal to a third output terminal, and a fourth transistor configured to amplify the high-frequency signal input from the second output terminal and to output the amplified high-frequency signal to the third output terminal through synthesis.

However, the low noise amplifier (LNA) including a feedback resistor has a problem in that it is difficult to detect a fault using a tester or the like due to the configuration including the feedback resistor.

### SUMMARY

The disclosure provides a low noise amplifier and a method of controlling an amplifier circuit.

According to the disclosure, there is provided a low noise amplifier including an amplifier circuit, the amplifier circuit including an amplification transistor configured to amplify a signal input from an input terminal and to output an amplified signal to a first node, a current mirror circuit configured to supply a bias current to the amplification transistor, a resistor provided on a feedback path for feeding an output of the first node back to the input terminal, and a first switch provided on the feedback path and configured to set up or cut off the feedback path, wherein the feedback path is cut off by the first switch when detection of a fault of the amplification transistor is performed.

According to the disclosure, there is provided a method of controlling an amplifier circuit, the amplifier circuit including an amplification transistor configured to amplify a signal input from an input terminal and to output an amplified signal to a first node, a current mirror circuit configured to supply a bias current to the amplification transistor, a resistor provided on a feedback path for feeding an output of the first node back to the input terminal, and a first switch provided on the feedback path and configured to set up or cut off the feedback path. The first switch is controlled to cut off the feedback path, when detection of a fault of the amplification transistor is performed.

According to the disclosure, it is possible to detect a fault in a low noise amplifier including a feedback resistor.

### BRIEF DESCRIPTION OF THE DRAWINGS

FIG. 1 is a circuit diagram illustrating a circuit configuration of a reception circuit.

FIG. 2 is a diagram schematically illustrating a direct-current test method for detecting a fault of an element connected to a terminal.

FIG. 3 is a circuit diagram illustrating a circuit configuration of a CMOS resistance feedback LAN according to the related art.

FIG. 4 is a circuit diagram illustrating a state in which a direct-current tester is connected to the resistance feedback LNA illustrated in FIG. 3.

FIG. 5 is a circuit diagram illustrating a circuit configuration of a resistance feedback LNA according to a first embodiment of the disclosure.

FIG. 6 is a circuit diagram illustrating a state when a direct-current test carried out on the resistance feedback LNA illustrated in FIG. 5.

FIG. 7 is a circuit diagram illustrating a state when the resistance feedback LNA illustrated in FIG. 5 operates.

FIG. 8 is a circuit diagram illustrating a state when the resistance feedback LNA illustrated in FIG. 5 stops its operation.

FIG. 9 is a circuit diagram illustrating a circuit configuration in which MOS switches are used as switches of the resistance feedback LNA illustrated in FIG. 5.

FIG. 10 is a circuit diagram illustrating a circuit configuration of a resistance feedback LNA according to a second embodiment of the disclosure.

FIG. 11 is a circuit diagram illustrating a state when a direct-current test is carried out on the resistance feedback LNA illustrated in FIG. 10.

### DESCRIPTION OF THE EMBODIMENTS

Hereinafter, an example of an embodiment of the disclosure will be described in detail with reference to the accompanying drawings.

### Reception Circuit Using LNA

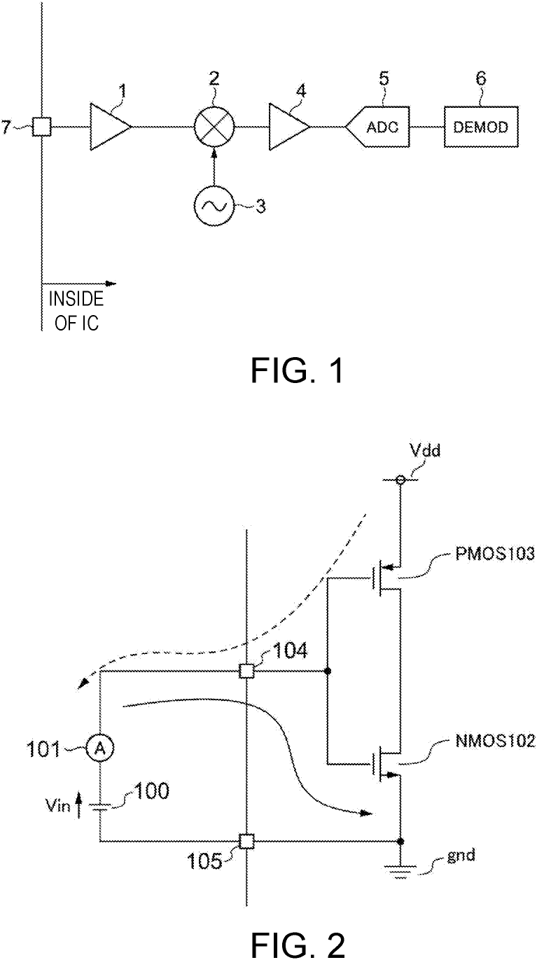

An LNA is used, for example, in a reception circuit illustrated in FIG. 1. FIG. 1 is a circuit diagram illustrating a circuit configuration of the reception circuit. The reception circuit is connected to an antenna (not illustrated), includes a low noise amplifier (LNA) 1, a mixer 2, a local oscillator 3, an analog amplifier 4, an analog-digital converter (ADC) 5, and a demodulator 6, and is integrated into an IC. The reception circuit is a circuit that performs processing such as amplification and frequency conversion on an input modulation signal and demodulates information of the signal, and operates as follows.

The LNA 1 amplifies an input weak high-frequency signal with low noise and outputs the amplified signal to the mixer 2. The local oscillator 3 generates a local signal for frequency conversion and outputs the generated signal to the mixer 2. The mixer 2 generates an intermediate-frequency signal by switching the high-frequency signal input from the LNA 1 using the signal input from the local oscillator 3. The generated intermediate-frequency signal is input to the analog amplifier 4. The analog amplifier 4 amplifies the signal input from the mixer 2 and outputs the amplified signal to the ADC 5. The ADC 5 converts the signal input from the analog amplifier 4 to a digital signal and outputs the digital signal to the demodulator 6. The demodulator 6 demodulates the digital conversion signal input from the ADC 8 and reads information.

Since an input terminal of the LNA 1 is connected to an IC terminal 7 as illustrated in FIG. 1, a high voltage may be applied to the LNA 1 due to electrostatic discharge (ESD), which may cause a fault of an element of the LNA 1. Accordingly, it is necessary to protect the input terminal of the LNA 1 from the ESD. In manufacturing processes, it is also necessary to inspect whether an element of the LNA 1 has a fault.

### Direct-Current Test

A direct-current test will be described below. FIG. 2 is a diagram schematically illustrating a direct-current test method for detecting a fault of an element connected to a terminal. In the following description, a P type MOS transistor is referred to as a PMOS, and an N type MOS transistor is referred to as an NMOS. In this test method, an IC terminal 104 and a ground terminal 105 of a tester are attached to a measurement target, and a voltage is applied across the IC terminal 104 and the ground terminal 105 from a voltage source 100. Then, a current value of a current flowing between the IC terminal 104 and the ground terminal 105 is measured by an ammeter 101, and it is inspected whether an abnormal current is detected.

In FIG. 2, it is assumed that a CMOS inverter circuit is connected as a measurement target. The inverter circuit includes a PMOS 103 and an NMOS 102. A source terminal of the PMOS 103 is connected to a source potential Vdd and a gate terminal thereof is connected to the IC terminal 104. A source terminal of the NMOS 102 is connected to a ground potential gnd and a gate terminal thereof is connected to the IC terminal 104.

The principle of fault detection will be described below. First, the voltage source 100 applies a voltage Vin=0 to detect a fault of the PMOS 103. When the PMOS 103 has no fault, an impedance between the gate and the source of the PMOS 103 is high, and thus no current flows therebetween and a current is hardly detected by the ammeter 101. When the PMOS 103 has a fault and the gate and the drain thereof are short-circuited, the PMOS 103 is diode-connected and the NMOS 102 is turned off. Accordingly, as indicated by a dotted arrow, a current generated in the PMOS 103 flows in the ammeter 101 and is detected by the ammeter 101. When the PMOS 103 has a fault and the gate and the source are short-circuited, the source potential Vdd and the ground potential gnd are short-circuited and thus a current is detected by the ammeter 101.

Then, the voltage source 100 applies a voltage Vin=Vdd to detect a fault of the NMOS 102. When the NMOS 102 has no fault, an impedance between the gate and the source of the NMOS 102 is high, and thus no current flows therebetween and a current is hardly detected by the ammeter 101. When the NMOS 102 has a fault and the gate and the drain thereof are short-circuited, the NMOS 102 is diode-connected. Accordingly, as indicated by a solid arrow, the NMOS 102 operates to extract a current from the voltage source 100, and a current is detected by the ammeter 101. When the NMOS 102 has a fault and the gate and the source are short-circuited, the voltage source 100 and the ground potential gnd are short-circuited and thus a current is detected by the ammeter 101.

As described above, with the direct-current test, since a current is not detected when an element has no fault and an abnormal current is detected when an element has a fault, it is possible to detect a fault of an element using a current value measured by the ammeter 101.

### LNA According to Related Art

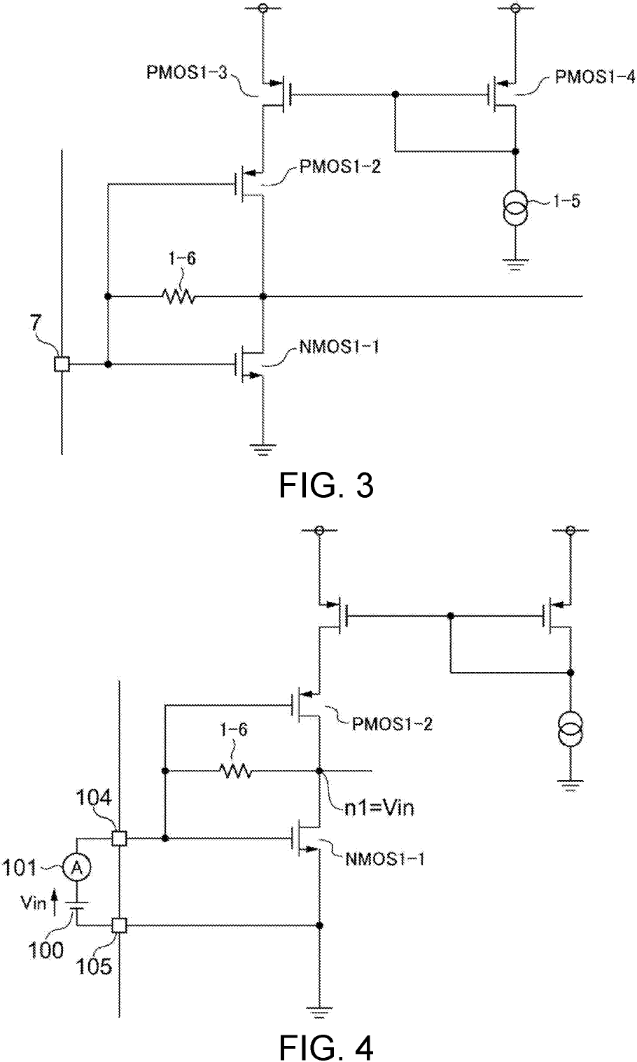

A circuit configuration of a resistance feedback LNA according to the related art will be described below with reference to FIG. 3. An LNA called a CMOS resistance feedback LNA will be described herein. As illustrated in FIG. 3, a CMOS resistance feedback LNA includes an NMOS 1-1, a PMOS 1-2, a PMOS 1-3, a PMOS 1-4, a current source 1-5, and a resistor 1-6. The resistor 1-6 is a resistor used for a feedback path and is connected between a drain terminal of the NMOS 1-1 and a gate terminal of the PMOS 1-2. The NMOS 1-1 and the PMOS 1-2 are directly connected to an IC terminal 7 and thus affected by ESD. Accordingly, it is necessary to ascertain whether such elements have a fault through a test process.

FIG. 4 is a circuit diagram illustrating a state in which a direct-current tester is connected to the resistance feedback LNA illustrated in FIG. 3. As can be seen from FIG. 4, a feedback resistor is an essential element for allowing the resistance feedback LNA to serve as an LNA, but a fault thereof cannot be detected using a tester or the like due to the configuration including the feedback resistor.

As described above, in the direct-current test, the IC terminal 104 and the ground terminal 105 of the tester are attached to a measurement target, a voltage is applied across the IC terminal 104 and the ground terminal 105 from the voltage source 100, and a current flowing between the IC terminal 104 and the ground terminal 105 is measured by the ammeter 101. Here, a node that is disposed between the drain terminal of the NMOS 1-1 and the drain terminal of the PMOS 1-2 and to which one end of the resistor 1-6 is connected is defined as a node n1.

When a voltage Vin=0 is applied using the voltage source 100 to detect a fault of the PMOS 1-2, the potential of the node n1 is also 0 due to the feedback path of the LNA. At this time, the gate and the drain of the PMOS 1-2 have the same potential and are diode-connected, and the NMOS 1-1 is turned off. Accordingly, the PMOS 1-2 causes a current supplied from the PMOS 1-3 to flow into the ammeter 101. As a result, the ammeter 101 detects a current regardless of whether the PMOS 1-2 has a fault and cannot detect the fault of the PMOS 1-2.

When a voltage Vin=Vdd is applied using the voltage source 100 to detect a fault of the NMOS 1-1, the potential of the node n1 is also Vdd due to the feedback path of the LNA. At this time, the gate and the drain of the NMOS 1-1 have the same potential and are diode-connected. The NMOS 1-1 is in a saturated operation area and extracts a current from the voltage source 100. As a result, the ammeter 101 detects a current regardless of whether the NMOS 1-1 has a fault and cannot detect the fault of the NMOS 1-1.

### First Embodiment

A first embodiment of the disclosure will be described below. A resistance feedback LNA according to the first embodiment is a CMOS resistance feedback LNA similarly to the LNA described above in an example according to the related art. The CMOS resistance feedback LNA can adjust an input impedance using a transconductance of a MOS and a resistance value of a feedback path. In general, since an input impedance of an LNA is designed to have a value equivalent to that of an external antenna (for example, 50 Ω,), it is necessary to prevent reflection of a signal. Accordingly, a resistance feedback type configuration that can adjust an input impedance may be used.

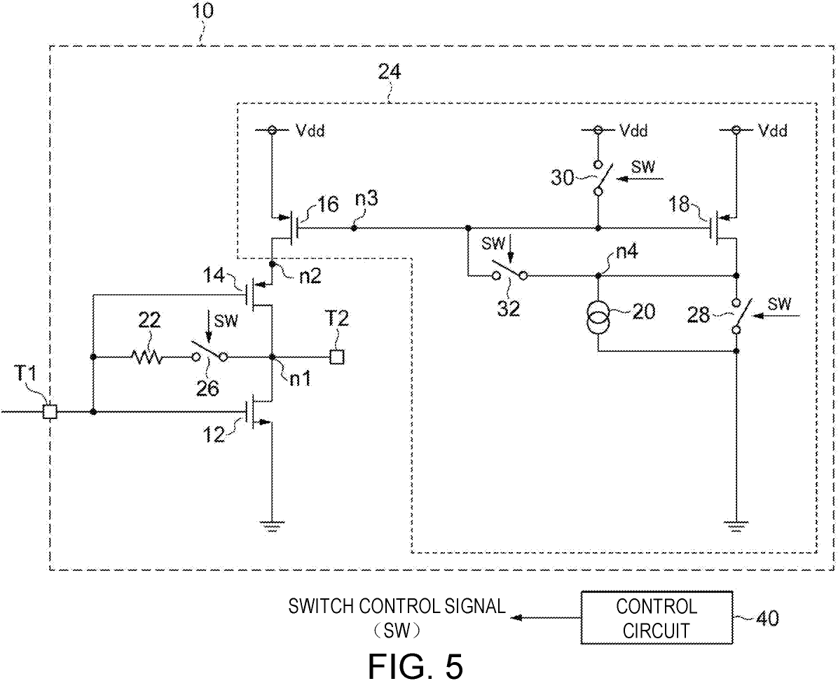

FIG. 5 is a circuit diagram illustrating a circuit configuration of the resistance feedback LNA according to the first embodiment of the disclosure. The LNA according to the first embodiment includes an amplifier circuit 10 configured to amplify an input signal with low noise and a control circuit 40 configured to control a plurality of switches included in the amplifier circuit 10. The control circuit 40 can be implemented, for example, by one or more electronic circuits including an IC, an LSI, or the like such as a register or a combination of registers. The control circuit 40 is connected to a controller (not illustrated) provided inside or outside of the LNA and outputs a switch control signal SW for controlling the switches in accordance with an instruction from the controller (not illustrated). The control circuit 40 may be provided outside of the LNA.

Similarly to the LNA according to the related art, the amplifier circuit 10 includes an NMOS 12, a PMOS 14, a PMOS 16, a PMOS 18, a current source 20, and a resistor 22. The amplifier circuit 10 includes a switch 26, a switch 28, a switch 30, and a switch 32 in addition to such elements.

The NMOS 12 is an amplification transistor configured to amplify a signal input to an input terminal T1. A gate terminal of the NMOS 12 is connected to the input terminal T1, a source terminal thereof is connected to a ground potential gnd, and a drain terminal thereof is connected to a node n1. An output terminal T2 for outputting an amplifier signal is connected to the node n1.

The PMOS 14 is an amplification transistor configured to amplify a signal input to the input terminal T1. A gate terminal of the PMOS 14 is connected to the input terminal T1, a source terminal thereof is connected to a node n2, and a drain terminal thereof is connected to the drain terminal of the NMOS 12.

The PMOS 16 is a PMOS transistor configured to supply a bias current to the NMOS 12 and the PMOS 14. A gate terminal of the PMOS 16 is connected to a node n3 and the switch 30, a source terminal thereof is connected to a source potential Vdd, and a drain terminal thereof is connected to the source terminal of the PMOS 14.

As will be described later, the switch 30 serves as a switch for pulling up the gate potential of the PMOS 16 when the LNA stops its amplifying operation. In a state in which the switch 30 is turned on, the gate terminal of the PMOS 16 is connected to the source potential Vdd. In a state in which the switch 30 is turned off, the gate terminal of the PMOS 16 and the source potential Vdd are disconnected, and the gate terminal of the PMOS 16 is connected to a gate terminal of the PMOS 18.

The PMOS 18 is a PMOS configured to supply a gate voltage for determining the bias current of the PMOS 16. A gate terminal of the PMOS 18 is connected to the gate terminal of the PMOS 16, a source terminal thereof is connected to the source potential Vdd, and a drain terminal is connected to the switch 28, the current source 20, and the switch 32.

As will be described later, the switch 28 serves as a switch for pulling down the gate potential of the PMOS 16 in the direct-current test. The switch 28 is disposed between the drain terminal of the PMOS 18 and the ground potential gnd. In a state in which the switch 28 is turned on, the drain terminal of the PMOS 18 is connected to the ground potential gnd. In a state in which the switch 28 is turned off, the gate terminal of the PMOS 18 and the ground potential gnd are disconnected, and the drain terminal of the PMOS 18 is connected to the current source 20.

The drain terminal and the gate terminal of the PMOS 18 are connected via the switch 32. The switch 32 serves as a switch for switching the gate terminal and the drain terminal of the PMOS 18 to an open state when the LNA stops its operation. In a state in which the switch 32 is turned on, the gate terminal and the drain terminal of the PMOS 18 are connected, and the PMOS 18 constitutes a current mirror circuit 24 along with the PMOS 16 and the current source 20. That is, the gate-source voltages of the PMOS 16 and the PMOS 18 are the same, and a magnitude ratio of currents flowing therein is equal to a size ratio of the PMOS 16 and the PMOS 18. In a state in which the switch 32 is turned off, the gate terminal and the drain terminal of the PMOS 18 are disconnected, and the gate terminal and the drain terminal of the PMOS 18 are in the open state.

The current source 20 is a circuit configured to supply a constant current to the PMOS 18 and is implemented as a constant current source circuit in an IC. One end of the current source 20 is connected to a node n4 on a path connecting the drain terminal and the gate terminal of the PMOS 18, and the other end thereof is connected to the ground potential gnd.

The resistor 22 is a resistor that is used for a feedback path. One end of the resistor 22 is connected to the switch 26, and the other end thereof is connected to the gate terminal of the NMOS 12 and the gate terminal of the PMOS 14. As will be described later, the switch 26 serves as a switch for switching the feedback path to an open state in the direct-current test. The feedback path is set up in a state in which the switch 26 is turned on, and the feedback path is cut off in a state in which the switch 26 is turned off.

The operations of the switches 26, 28, 30, and 32 and the PMOS 16 will be summarized below. The switches 26, 28, 30, and 32 and the PMOS 16 are controlled in their ON/OFF states as described below in Table 1 when the direct-current test is performed, when the LNA operates, and when the LNA stops its operation.

TABLE 1

| | | | | | |
|---|---|---|---|---|---|
| State | PMOS 16 | Switch 28 | Switch 26 | Switch 30 | Switch 32 |
| Direct-current test | ON | ON | OFF | OFF | ON |
| Operation | ON | OFF | ON | OFF | ON |
| Operation stop | OFF | ON | ON | ON | OFF |

For example, when connection of a tester is detected, a controller (not illustrated) instructs the control circuit 40 to switch the LNA to the state when the direct-current test is performed. When an IC is switched to a signal receiving mode, the controller (not illustrated) instructs the control circuit 40 to switch the LNA to the state when the LNA operates. Otherwise, the controller (not illustrated) instructs the control circuit 40 to switch the LNA to the state when the LNA stops its operation. The control circuit 40 outputs a switch control signal SW in accordance with an instruction from the controller such that the switches are turned on or off.

### (When Direct-Current Test is Performed)

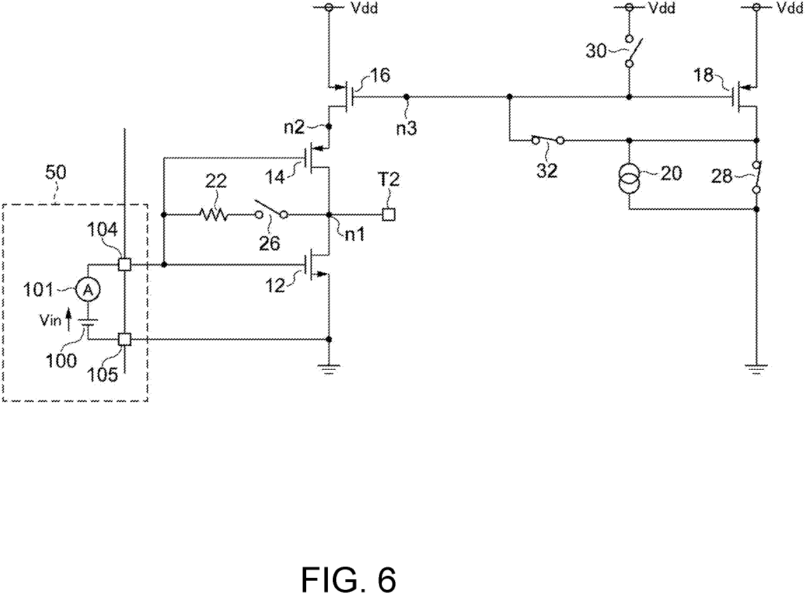

FIG. 6 is a circuit diagram illustrating a state when a direct-current test of the resistance feedback LNA illustrated in FIG. 5 is performed. In the direct-current test, a tester 50 including a voltage source 100, an ammeter 101, an IC terminal 104, and a ground terminal 105 is attached to an LNA which is a measurement target. The IC terminal 104 of the tester 50 is connected to the input terminal T1 of the LNA. As described in Table 1, the control circuit 40 outputs a switch control signal SW such that the switches 26 and 30 are turned off and the switches 28 and 32 are turned on.

When the switch 28 and the switch 32 are turned on, the node n3 is connected to the ground potential gnd, and the gate potential of the PMOS 16 is pulled down. Accordingly, the PMOS 16 is turned on. That is, the PMOS 16 operates as a switch, connects the node n2 between the drain terminal of the PMOS 16 and the source terminal of the PMOS 14 to the source potential Vdd, and pulls up the potential of the node n2.

The switch 26 is turned off to open the gate terminal and the drain terminal of each of the NMOS 12 and the PMOS 14. As a result, the resistance feedback LNA is equivalent to a CMOS inverter circuit in which the source terminal of the PMOS 14 is connected to the source potential Vdd and the source terminal of the NMOS 12 is connected to the ground potential gnd.

A voltage Vin=0 is applied using the voltage source 100 to detect a fault of the PMOS 14. When the PMOS 14 has no fault, a current does not flow due to a high impedance between the gate terminal and the source terminal of the PMOS 14, and a current is hardly detected by the ammeter 101. When the PMOS 14 has a fault and the gate terminal and the drain terminal thereof are short-circuited, the PMOS 14 is diode-connected and the NMOS 102 is turned off. Accordingly, a current generated in the PMOS 14 flows in the ammeter 101 and is detected by the ammeter 101. When the PMOS 14 has a fault and the gate terminal and the source terminal thereof are short-circuited, the source potential Vdd and the ground potential gnd are short-circuited and thus a current is detected by the ammeter 101.

A voltage Vin=Vdd is applied using the voltage source 100 to detect a fault of the NMOS 12. When the NMOS 12 has no fault, a current does not flow due to a high impedance between the gate terminal and the source terminal of the NMOS 12, and a current is hardly detected by the ammeter 101. When the NMOS 12 has a fault and the gate terminal and the drain terminal thereof are short-circuited, the NMOS 12 is diode-connected. Accordingly, the NMOS 12 operates to extract a current from the voltage source 100, and a current is detected by the ammeter 101. When the NMOS 12 has a fault and the gate terminal and the source terminal thereof are short-circuited, the voltage source 100 and the ground potential gnd are short-circuited and thus a current is detected by the ammeter 101.

When the direct-current test is performed in the aforementioned state in this way, a current can be detected only when the NMOS 12 or the PMOS 14 has a fault, and thus it is possible to detect a fault of an element in the LNA.

### (When LNA Operates)

On the other hand, when the LNA performs an amplification operation, the control circuit 40 outputs the switch control signal SW as described above in Table 1 such that the switches 28 and 30 are turned off and the switches 26 and 32 are turned on.

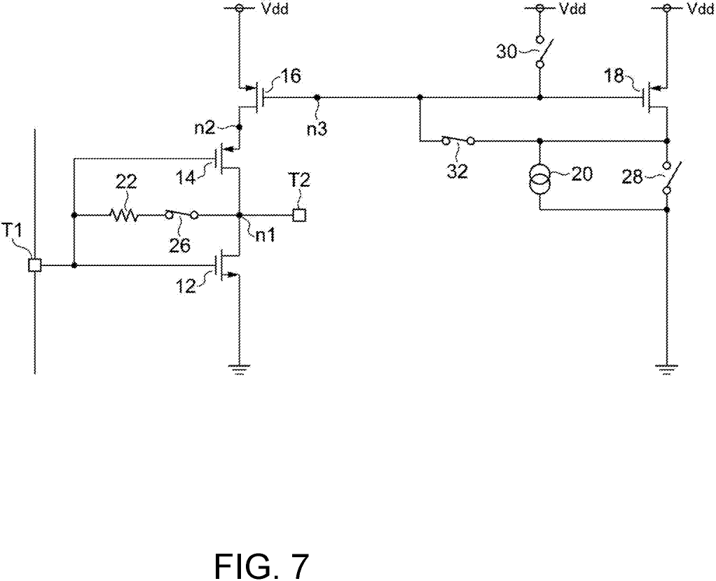

FIG. 7 is a circuit diagram illustrating a state when the resistance feedback LNA illustrated in FIG. 5 operates. When the switch 26 is turned on, the feedback path including the resistor 22 is set up. When the switches 28 and 30 are turned off and the switch 32 is turned on, the gate terminal of the PMOS 16 and the gate terminal and the drain terminal of the PMOS 18 are connected, the PMOS 16 forms the current mirror circuit 24 along with the PMOS 18 and the current source 20. Accordingly, the LNA operates in the same way as the resistance feedback LNA according to the related art.

The operations of the LNA will be described below. A constant current is supplied from the current source 20 which is a constant current source circuit to the PMOS 18. The gate-source voltages of the PMOS 16 and the PMOS 18 constituting the current mirror circuit 24 are the same, and a current flows in the PMOS 16 according to the size ratio of the PMOS 16 and the PMOS 18. The current flowing in the PMOS 16 is supplied as a bias current to the NMOS 12 and the PMOS 14. The NMOS 12 and the PMOS 14 amplify a signal which is biased with the bias current and input from the input terminal T1 and outputs the amplifier signal from the output terminal T2.

The resistor 22 can decrease the input impedance of the LNA to match the impedance with that of an external antenna by feeding back a noise voltage generated in the drain terminals of the NMOS 12 and the PMOS 14 to the input terminal T1.

### (When LNA Stops Operation)

When the LNA stops its amplifying operation, the control circuit 40 outputs the switch control signal SW as described in Table 1 such that the switch 32 is turned off and the switches 26, 28, and 30 are turned on.

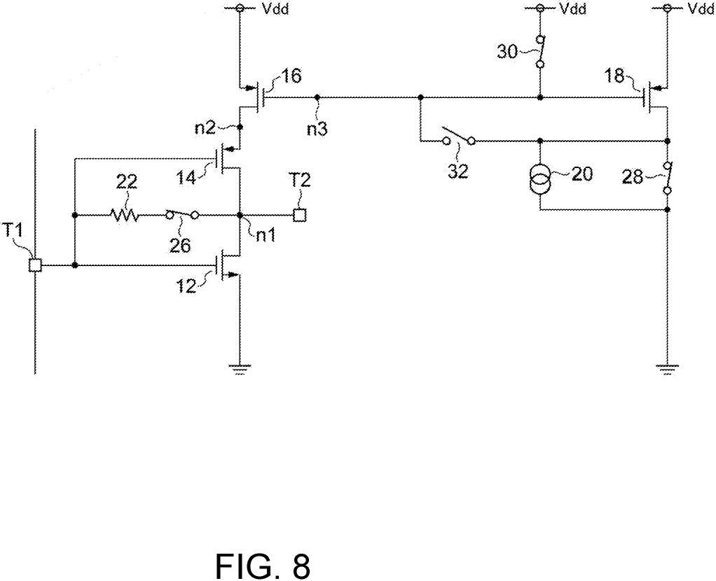

FIG. 8 is a circuit diagram illustrating a state when the resistance feedback LNA illustrated in FIG. 5 stops its operation. When the switch 26 is turned on, the feedback path including the resistor 22 is set up. When the switch 28 is turned on and the switch 32 is turned off, the terminals of the current source 20 are short-circuited and no current is generated therefrom. When the switch 30 is turned on, the gate terminal of the PMOS 16 is connected to the source potential Vdd and the gate potential of the PMOS 16 is pulled up. As a result, the PMOS 16 is turned off to cut off the bias current. When the switch 32 is turned off, a current path from the switch 30 to the switch 28 is cut off. As a result, the LNA can cut off a current when it stops its operation.

### (Examples of Switch)

The switches 26, 28, 30, and 32 are not particularly limited as long as they can switch between the ON state and the OFF state. For example, a MOS switch such as an NMOS switch, a PMOS switch, or a CMOS switch can be used as the switches 26, 28, 30, and 32.

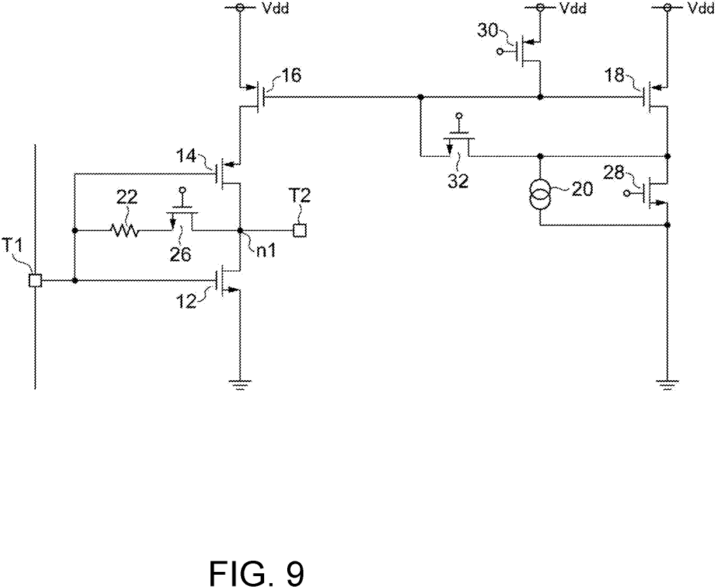

FIG. 9 is a circuit diagram illustrating a circuit configuration in which a MOS switch is used as the switches of the resistance feedback LNA illustrated in FIG. 5. In this example, NMOS switches are used as the switch 26, the switch 28, and the switch 32, and a PMOS switch is used as the switch 30. The control circuit 40 outputs a switch control signal SW to switch the switches such that a voltage based on the switch control signal SW is applied to the gate terminals of the NMOS switches and the PMOS switch.

As described above in detail, in the first embodiment, since the switches 26, 28, 30, and 32 are added to the LNA, it is possible to detect a current through a direct-current test and to detect a fault only when at least one of the PMOS and the NMOS connected to the input terminal has a fault by cutting off the feedback path of the LNA, connecting the source terminal of the PMOS 14 to the source potential Vdd, and connecting the source terminal of the NMOS 12 to the ground potential gnd when the direct-current test of the LNA is performed.

In the first embodiment, since the switches 26, 28, 30, and 32 are added to the LNA, it is possible to cut off a current and to curb current consumption by switching the current source 20 to a state in which the terminals are short-circuited not to generate a current and connecting the gate terminal of the PMOS 16 to the source potential Vdd when the LNA stops its operation.

### Second Embodiment

A second embodiment is the same as the first embodiment except that the resistance feedback LNA is replaced with an NMOS resistance feedback LNA. Accordingly, the same elements will be referred to by the same reference signs and description thereof will be omitted.

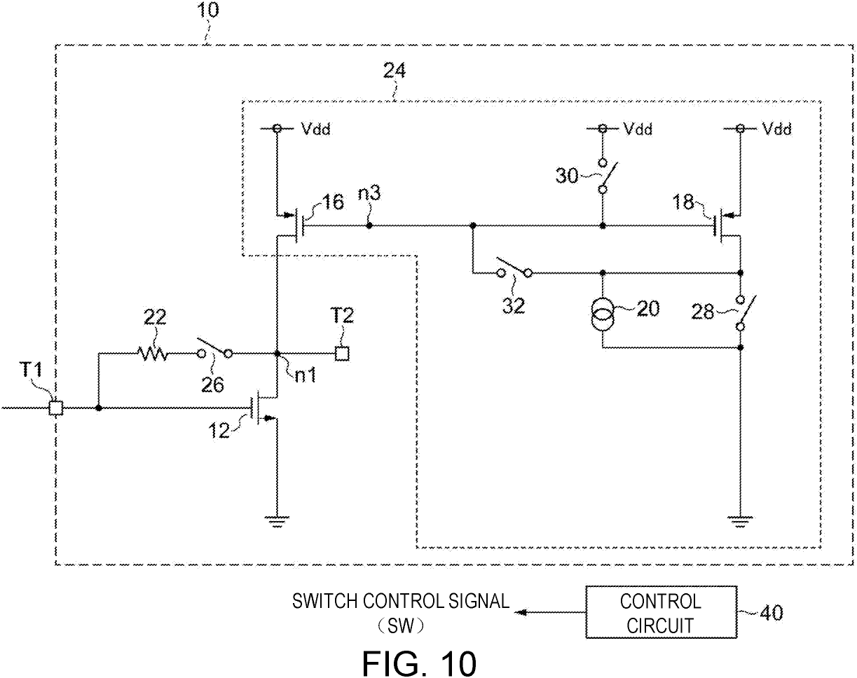

FIG. 10 is a circuit diagram illustrating a circuit configuration of a resistance feedback LNA according to the second embodiment of the disclosure. The NMOS resistance feedback LNA has a circuit configuration in which the PMOS 14 is removed from the CMOS resistance feedback LNA described above in the first embodiment. With this circuit configuration, it is also possible to adjust the input impedance using the transconductance of the NMOS 12 and the resistance value of the feedback path, and the LNA can operate.

The operations of the switches 26, 28, 30, and 32 and the PMOS 16 will be summarized below. The switches 26, 28, 30, and 32 and the PMOS 16 are controlled in their ON/OFF states as described below in Table 2 when the direct-current test is performed, when the LNA operates, and when the LNA stops its operation. Switch control when the LNA operates and when the LNA stops its operation is the same as in the first embodiment.

TABLE 2

| | | | | | |
|---|---|---|---|---|---|
| State | PMOS 16 | Switch 28 | Switch 26 | Switch 30 | Switch 32 |
| Direct-current test | OFF | OFF | OFF | OFF | OFF |
| Operation | ON | OFF | ON | OFF | ON |
| Operation stop | OFF | ON | ON | ON | OFF |

### (When Direct-Current Test is Performed)

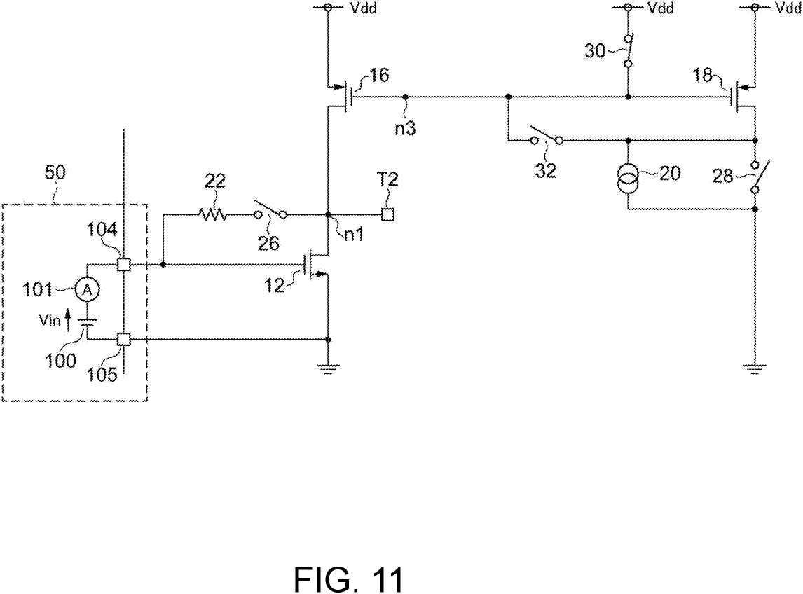

FIG. 11 is a circuit diagram illustrating a state when a direct-current test of the resistance feedback LNA illustrated in FIG. 10 is performed. In the direct-current test, as described in Table 2, the control circuit 40 outputs a switch control signal SW such that the switches 26, 28, and 32 are turned off and the switch 30 is turned on.

When the switch 28 and the switch 32 are turned off and the switch 30 is turned on, the node n3 is connected to the source potential Vdd, and the gate potential of the PMOS 16 is pulled up. Accordingly, the PMOS 16 is turned off. The switch 26 is turned off, and the gate terminal and the drain terminal of the NMOS 12 are made to be open. As a result, the drain terminal of the NMOS 12 of the resistance feedback LNA is in a high-impedance state. When the drain terminal of the NMOS 12 is short-circuited to another node, its potential is the same as the potential of the short-circuited node.

The direct-current test is performed in this state. When the voltage Vin-Vdd is applied using the voltage source 100 of the tester, a current is hardly detected by the ammeter 101 when the NMOS 12 has no fault. When the NMOS 12 has a fault and the gate terminal and the drain terminal thereof are short-circuited, the NMOS 12 is diode-connected and a current is detected when the voltage Vin is applied. When the gate terminal and the source terminal thereof are short-circuited, a current flows from the voltage source 100 to the ground potential gnd and a current is detected. As a result, it is possible to detect a current only when the NMOS 12 has a fault and to detect a fault of an element in the LNA.

The states when the LNA operates and when the LNA stops its operation are the same as in the first embodiment and thus description thereof will be omitted.

In the second embodiment, since the switches 26, 28, 30, and 32 are added to the LNA, it is possible to detect a current through the direct-current test and to detect a fault only when the NMOS connected to the input terminal has a fault by cutting off the feedback path of the LNA, connecting the source terminal of the NMOS 12 to the ground potential gnd, switching the drain terminal of the NMOS 12 to a high-impedance state to have the same potential as that of another short-circuited node when it is short-circuited to the other node at the time of performing the direct-current test of the LNA.

Similarly to the first embodiment, when the LNA stops its operation, it is possible to cut off a current and to curb current consumption by switching the current source 20 to a state in which the terminals thereof are short-circuited not to generate a current and connecting the gate terminal of the PMOS 16 to the source potential Vdd.

### Modified Examples

The configurations of the low noise amplifier and the control method thereof described above in the embodiments are only examples, and the configurations can also be modified without departing from the gist of the disclosure.

For example, the control circuit is implemented as a hardware configuration in the aforementioned embodiments, but the functions of the control circuit may be implemented as a software configuration by causing a processor to execute a program. The functions of the control circuit may be implemented by combination of the hardware configuration and the software configuration.

It will be apparent to those skilled in the art that various modifications and variations can be made to the disclosed embodiments without departing from the scope or spirit of the disclosure. In view of the foregoing, it is intended that the disclosure covers modifications and variations provided that they fall within the scope of the following claims and their equivalents.

What is claimed is:

1. A low noise amplifier comprising an amplifier circuit, the amplifier circuit including an amplification transistor configured to amplify a signal input from an input terminal and to output an amplified signal to a first node, a current mirror circuit configured to supply a bias current to the amplification transistor, a resistor provided on a feedback path for feeding an output of the first node back to the input terminal, and a first switch provided on the feedback path and configured to set up or cut off the feedback path,
wherein the feedback path is cut off by the first switch when detection of a fault of the amplification transistor is performed.

2. The low noise amplifier according to claim 1, wherein the feedback path is set up by the first switch when the amplifier circuit performs an amplifying operation or stops the amplifying operation.

3. The low noise amplifier according to claim 1, wherein the amplification transistor includes a first transistor and a second transistor which are connected in series, and the first transistor and the second transistor form an inverter circuit when the feedback path is cut off.

4. The low noise amplifier according to claim 1, wherein the amplification transistor is a first transistor which is a P type MOS transistor or an N type MOS transistor.

5. The low noise amplifier according to claim 3, wherein the current mirror circuit includes:
a third transistor connected between a first source potential and the amplification transistor;
a current source of which one end is connected to a ground potential;
a fourth transistor connected between a second source potential and the current source and including a gate terminal connected to a gate terminal of the third transistor; and
a plurality of switches configured to switch circuit connection, and
wherein the third transistor is made to serve as a switch connecting the first source potential and the amplification transistor using the plurality of switches when the detection of the fault of the amplification transistor is performed.

6. The low noise amplifier according to claim 4, wherein the current mirror circuit includes:
a third transistor connected between a first source potential and the amplification transistor;
a current source of which one end is connected to a ground potential;
a fourth transistor connected between a second source potential and the current source and including a gate terminal connected to a gate terminal of the third transistor; and
a plurality of switches configured to switch circuit connection, and
wherein one end of the first transistor is switched to a high-impedance state using the plurality of switches when the detection of the fault of the amplification transistor is performed.

7. The low noise amplifier according to claim 5, wherein the plurality of switches includes:
a second switch configured to connect or disconnect the gate terminal of the third transistor and the ground potential and to short-circuit an input end and an output end of the current source when the gate terminal of the third transistor and the ground potential are connected;
a third switch configured to connect or disconnect the gate terminal of the third transistor and a third source potential; and
a fourth switch configured to connect or disconnect the gate terminal and a drain terminal of the fourth transistor, and
wherein, when the detection of the fault of the amplification transistor is performed, the gate terminal of the third transistor and the ground potential are connected and the input end and the output end of the current source are short-circuited using the second switch,
the gate terminal of the third transistor and the third source potential are disconnected using the third switch, and
the gate terminal and the drain terminal of the fourth transistor are connected using the fourth switch.

8. The low noise amplifier according to claim 6, wherein the plurality of switches includes:
a second switch configured to connect or disconnect the gate terminal of the third transistor and the ground potential and to short-circuit an input end and an output end of the current source when the gate terminal of the third transistor and the ground potential are connected;
a third switch configured to connect or disconnect the gate terminal of the third transistor and a third source potential; and
a fourth switch configured to connect or disconnect the gate terminal and a drain terminal of the fourth transistor, and
wherein, when the detection of the fault of the amplification transistor is performed, the gate terminal of the third transistor and the ground potential are disconnected using the second switch,
the gate terminal of the third transistor and the third source potential are connected using the third switch, and
the gate terminal and the drain terminal of the fourth transistor are disconnected using the fourth switch.

9. The low noise amplifier according to claim 5, wherein the current mirror circuit supplies a bias current using the plurality of switches when the amplifier circuit performs an amplification operation.

10. The low noise amplifier according to claim 5, wherein the current mirror circuit cuts off a bias current using the plurality of switches when the amplifier circuit stops an amplification operation.

11. The low noise amplifier according to claim 1, further comprising a control circuit configured to control the first switch.

12. The low noise amplifier according to claim 11, wherein the control circuit controls the plurality of switches.

13. A method of controlling an amplifier circuit, the amplifier circuit including an amplification transistor configured to amplify a signal input from an input terminal and to output an amplified signal to a first node, a current mirror circuit configured to supply a bias current to the amplification transistor, a resistor provided on a feedback path for feeding an output of the first node back to the input terminal, and a first switch provided on the feedback path and configured to set up or cut off the feedback path,
wherein the first switch is controlled to cut off the feedback path, when detection of a fault of the amplification transistor is performed.

14. The method of controlling an amplifier circuit according to claim 13, wherein the amplification transistor includes a first transistor and a second transistor which are connected in series,
wherein the current mirror circuit includes:
a third transistor connected between a first source potential and the amplification transistor;
a current source of which one end is connected to a ground potential;
a fourth transistor connected between a second source potential and the current source and including a gate terminal connected to a gate terminal of the third transistor; and
a plurality of switches configured to switch circuit connection, and
wherein the third transistor is made to serve as a switch connecting the first source potential and the amplification transistor by controlling the plurality of switches when the detection of the fault of the amplification transistor is performed.

15. The method of controlling an amplifier circuit according to claim 14, wherein the amplification transistor is the first transistor,
wherein the current mirror circuit includes:
a third transistor connected between a first source potential and the amplification transistor;
a current source of which one end is connected to a ground potential;
a fourth transistor connected between a second source potential and the current source and including a gate terminal connected to a gate terminal of the third transistor; and
a plurality of switches configured to switch circuit connection, and
wherein the plurality of switches is controlled such that one end of the first transistor is in a high impedance state when the detection of the fault of the amplification transistor is performed.

16. The low noise amplifier according to claim 2, wherein the amplification transistor includes a first transistor and a second transistor which are connected in series, and the first transistor and the second transistor form an inverter circuit when the feedback path is cut off.

17. The low noise amplifier according to claim 2, wherein the amplification transistor is a first transistor which is a P type MOS transistor or an N type MOS transistor.
